(19) United States
(12) Patent Application Publication
(10) Pub. No.: US 2025/0391770 A1
(43) Pub. Date: Dec. 25, 2025

(54) INTEGRATED CIRCUIT INCLUDING MULTIPLE DEVICE LAYERS

(71) Applicant: International Business Machines Corporation, Armonk, NY (US)

(72) Inventors: Shay Reboh, Albany, NY (US); Tenko Yamashita, Schenectady, NY (US); Huiming Bu, Glenmont, NY (US); Chen Zhang, Santa Clara, CA (US); James P. Mazza, Saratoga Springs, NY (US); Ruilong Xie, Niskayuna, NY (US)

(21) Appl. No.: 18/748,446

(22) Filed: Jun. 20, 2024

(51) Int. Cl. H01L 23/528; H01L 25/065; H01L 27/092

(52) U.S. Cl. CPC H01L 23/5286; H01L 25/0657; H10D 84/856; H01L 2225/06541

(57) ABSTRACT

An integrated circuit includes at least three vertically arranged device layers, which are separated from one another by a horizontal space and at least one vertically extending device column. A semiconductor device is disposed in each of the at least three device layers and is aligned vertically in the device column. At least one vertically extending first-type signal line column includes a plurality of first-type signal line pairs that extend through the horizontal space to establish a first electrical connection with the at least one semiconductor device disposed in the at least three device layers. At least one second-type signal line column extends vertically and includes at least one second-type signal line that establishes a second electrical connection with the at least one semiconductor device disposed in the at least three device layers.

### BACKGROUND

The present invention generally relates to integrated circuits, and more specifically, to an integrated circuit including multiple device layers.

Integrated circuits or ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a fin type field effect transistor (FET), which is a type of nonplanar MOSFET formed a three-dimensional structure. FinFET devices include an arrangement of fins disposed on a substrate. The fins are formed from a semiconductor material. A gate stack is arranged over the fins and defines a channel region of the fins, while regions of the fins extending outwardly from the channel region define active source and drain regions of the device.

Another 3D device is the nanowire or nanosheet MOSFET, which is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure.

### SUMMARY

Embodiments of the present invention are directed to an interconnect structure including multiple device layers. According to a non-limiting embodiment, an integrated circuit extends along a first axis between a first end and a second end located opposite the first end to define a length, extends along a second axis orthogonal to the first axis between a third end and a fourth end located opposite the third end to define a width, and extends along a third axis orthogonal to the first and second axes between a frontside of the integrated circuit and a backside of the integrated circuit to define a vertical height. The integrated circuit comprises at least three device layers, at least one semiconductor device, at least one first-type signal line column, and at least one second-type signal line column. The at least three device layers are arranged along the third axis. The at least three device layers are also separated from one another by a horizontal space extending along the second axis and at least one at least one device column extending along the third axis. The at least one semiconductor device is disposed in each of the at least three device layers and is aligned vertically in the at least one device column. The at least one first-type signal line column extends along the third axis and includes a plurality of first-type signal line pairs that extends along the first axis to establish a first electrical connection with the at least one semiconductor device disposed in the at least three device layers. The at least one second-type signal line column extends along the third axis and includes at least one second-type signal line that extends along the second axis to establish a second electrical connection with the at least one semiconductor device disposed in the at least three device layers.

According to another non-limiting embodiment, an integrated circuit (IC) chip comprises and an IC. The IC comprises at least three device layers, at least one semiconductor device, a first power signal line column, a second power signal line column, a first data signal line column, and a second data signal line column. The at least three device layers are arranged along a vertical axis, and are separated from one another by a horizontal space extending along a first horizontal axis and by at least one device column extending along the vertical axis. The at least one semiconductor device is disposed in each of the at least three device layers and in the at least one device column. The first power signal line column extends along the vertical axis and is disposed on a first end of the IC. The second power signal line column extends along the vertical axis and disposed on a second end of the IC opposite the first end. The first data signal line column extends along the vertical axis and is disposed on a third end of the IC. The second data signal line column extends along the vertical axis and is disposed on a fourth end of the IC opposite the third end.

According to yet another non-limiting embodiment, an electrical circuit comprises a first integrated circuit and a second integrated circuit electrically connected to the first integrated circuit. Each of the first integrated circuit and the second integrated circuit comprises at least three device layers, at least one semiconductor device, at least one power signal line column, and at least one data signal line column. The at least three device layers are arranged along a vertical axis, and are separated from one another by a horizontal space extending along a first horizontal axis and by at least one device column extending along the vertical axis. The at least one semiconductor device is disposed in each of the at least three device layers and in the at least one device column. The at least one power signal line column extends along the vertical axis and is disposed on a first end of the IC. The at least one data signal line column extends along the vertical axis and is disposed on a second end of the IC.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A is a top-view of an integrated circuit including an interconnect structure having multiple device layers according to one or more embodiments of the present disclosure;

FIG. 1B depicts a logic slice of the integrated circuit shown in FIG. 1A;

FIG. 2A is a top view of the logic slice shown in FIG. 1B;

FIG. 2B is a cross-sectional view of the logic slice shown in FIG. 1B taken along line X1-X1 depicting an interconnect structure included in the integrated circuit;

FIG. 2C is a cross-sectional view of the logic slice shown in FIG. 1B taken along line X2-X2 depicting the interconnect structure included in the integrated circuit;

FIG. 3 is a top view of a semiconductor device included in the logic slice of the integrated circuit shown in FIG. 1B in a second orientation according to one or more embodiments of the present disclosure;

FIG. 4A is a top view of a logic slice of an integrated circuit according to one or more embodiments of the present disclosure;

FIG. 4B is cross-sectional view of the logic slice shown in FIG. 4A taken along line X1-X1 depicting an interconnect structure included in the integrated circuit according to one or more embodiments of the present disclosure;

FIG. 5 depicts an interconnect structure included in the integrated circuit shown in FIG. 1B in a second orientation;

FIG. 6 depicts an interconnect structure included in the logic slice of the integrated circuit shown in FIG. 1B in the second orientation according to one or more embodiments of the present disclosure;

FIG. 7 depicts the logic slice of the integrated circuit shown in FIG. 1B following the formation of a frontside backend-of-line (BEOL) metal level and backside power distribution network according to one or more embodiments of the present disclosure;

FIG. 8A is an integrated circuit chip (IC chip) implementing an interconnect structure according to one or more embodiments of the present disclosure;

FIG. 8B is block diagram of the IC chip shown in FIG. 8A;

FIG. 9 is an electrical circuit implementing a plurality of the IC chips shown in FIGS. 8A and 8B according to one or more embodiments of the present disclosure;

FIG. 10 is a top down view of an electrical circuit including a first integrated circuit having a first interconnect structure connected to a second integrated circuit according to one or more embodiments of the present disclosure; and

FIG. 11 is a top down view of an electrical circuit including a first integrated circuit having a first interconnect structure connected to a second integrated circuit according to one or more embodiments of the present disclosure.

### DETAILED DESCRIPTION

According to a non-limiting embodiment of the disclosure, an integrated circuit extends along a first axis between a first end and a second end located opposite the first end to define a length, extends along a second axis orthogonal to the first axis between a third end and a fourth end located opposite the third end to define a width, and extends along a third axis orthogonal to the first and second axes between a frontside of the integrated circuit and a backside of the integrated circuit to define a vertical height. The integrated circuit comprises at least three device layers, at least one semiconductor device, at least one first-type signal line column, and at least one second-type signal line column. The at least three device layers are arranged along the third axis. The at least three device layers are also separated from one another by a horizontal space extending along the second axis and at least one at least one device column extending along the third axis. The at least one semiconductor device is disposed in each of the at least three device layers and is aligned vertically in the at least one device column. The at least one first-type signal line column extends along the third axis and includes a plurality of first-type signal line pairs that extends along the first axis to establish a first electrical connection with the at least one semiconductor device disposed in the at least three device layers. The at least one second-type signal line column extends along the third axis and includes at least one second-type signal line that extends along the second axis to establish a second electrical connection with the at least one semiconductor device disposed in the at least three device layers. Accordingly, the unique connection provides a semiconductor device having a reduced scaling on the integrated circuit along the vertical axis (e.g., the Z-axis).

In some embodiments, a pair of vertically aligned semiconductor devices among the at least three device layers form a stacked complimentary metal-oxide semiconductor (CMOS) device. Accordingly, the unique connection provides a CMOS device having a reduced scaling on the integrated circuit along the vertical axis (e.g., the Z-axis).

In some embodiments, the plurality of first-type signal line pairs are established as first and second power signal lines, and the at least one second-type signal line is established as a data signal line. Accordingly, power signals and data signals can be provided to the semiconductor devices in the integrated circuit while still providing a semiconductor device having a reduced scaling on the integrated circuit along the vertical axis (e.g., the Z-axis).

In some embodiments, each of the first and second power signal lines include a vertical power line portion extending vertically along the third axis and a plurality of horizontal power line portions. Accordingly, power signals and data signals can be provided to the semiconductor devices in the integrated circuit without limiting the scaling of the semiconductor device along the vertical axis (e.g., the Z-axis).

In some embodiments, each of the plurality of horizontal power line portions extend along the first axis to provide power to the semiconductor device. Accordingly, power signals can be provided to the semiconductor devices in the integrated circuit without limiting the scaling of the semiconductor device along a horizontal axis (e.g., the X-axis)

In some embodiments, each of the plurality of horizontal power line portions are arranged side-by-side with respect to one another. Accordingly, power signals can be provided to the semiconductor devices in the integrated circuit while reducing the scaling of the semiconductor device along a vertical axis (e.g., the Z-axis).

In some embodiments, each of the plurality of horizontal power line portions are vertically aligned along the third axis with respect to one another. Accordingly, power signals can be provided to the semiconductor devices in the integrated circuit while reducing the scaling of the semiconductor device along a horizontal axis (e.g., the Y-axis).

In some embodiments, the vertical power line portion includes a plurality of vertically stacked signal vias formed from an electrically conductive material. Accordingly, the signal vias can electrically connect rows of semiconductor devices to the front or to the back-side of the integrated circuit.

In some embodiment, the at least one semiconductor device included in a first device layer among the at least three device layers is an n-type field effect transistor (NFET) and the at least one semiconductor device included in a second device layer among the at least three device layers is a p-type field effect transistor (PFET). Accordingly, a CMOS device having a reduced scaling on the integrated circuit along the vertical axis (e.g., the Z-axis) can be provided.

In some embodiments, the at least one semiconductor device included in a first device layer among the at least three device layers is an p-type field effect transistor (PFET) and the at least one semiconductor device included in a second device layer among the at least three device layers is an n-type field effect transistor (NFET). Accordingly, a CMOS device having a reduced scaling on the integrated circuit along the vertical axis (e.g., the Z-axis) can be provided.

In some embodiments, the at least one first-type signal line column includes a pair of first-type signal line columns disposed adjacent to the first end and the second end of the integrated circuit, respectively. Accordingly, VSS and VDD power signals can be provided to the semiconductor devices in an integrated circuit while reducing the scaling of a CMOS device along a vertical axis (e.g., the Z-axis).

In some embodiments, the at least one second-type signal line column includes a pair of second-type signal line columns disposed adjacent to the third end and the fourth end of the integrated circuit, respectively. Accordingly, various data signals can be communicated to and/or from the semiconductor devices in an integrated circuit while reducing the scaling of a CMOS device along a vertical axis (e.g., the Z-axis).

In some embodiments, a backend-of-line (BEOL) metal level is disposed on a frontside of the integrated circuit, and a power distribution network on a backside of the of the integrated circuit. Accordingly, a BEOL metal level and power distribution network can be disposed on an integrated circuit, while reducing the scaling of a CMOS device along a vertical axis (e.g., the Z-axis).

In some embodiments, the first power signal line is a voltage source (VSS) power line, the second power signal line is a voltage drain (VDD) power line, and the at least one second-type signal line includes a plurality of data signal lines. Accordingly, the scaling of an integrated circuit including one more stacked CMOS devices can be reduced along a vertical axis (e.g., the Z-axis) while still providing VSS signal lines, VDD signal lines, and a plurality of data signal lines.

According to another non-limiting embodiment, an integrated circuit (IC) chip comprises and an IC. The IC comprises at least three device layers, at least one semiconductor device, a first power signal line column, a second power signal line column, a first data signal line column, and a second data signal line column. The at least three device layers are arranged along a vertical axis, and are separated from one another by a horizontal space extending along a first horizontal axis and by at least one device column extending along the vertical axis. The at least one semiconductor device is disposed in each of the at least three device layers and in the at least one device column. The first power signal line column extends along the vertical axis and is disposed on a first end of the IC. The second power signal line column extends along the vertical axis and disposed on a second end of the IC opposite the first end. The first data signal line column extends along the vertical axis and is disposed on a third end of the IC. The second data signal line column extends along the vertical axis and is disposed on a fourth end of the IC opposite the third end. Accordingly, an integrated circuit (IC) chip can be provided having a reduced scaling on the integrated circuit along the vertical axis (e.g., the Z-axis).

According to yet another non-limiting embodiment, an electrical circuit comprises a first integrated circuit and a second integrated circuit electrically connected to the first integrated circuit. Each of the first integrated circuit and the second integrated circuit comprises at least three device layers, at least one semiconductor device, at least one power signal line column, and at least one data signal line column. The at least three device layers are arranged along a vertical axis, and are separated from one another by a horizontal space extending along a first horizontal axis and by at least one device column extending along the vertical axis. The at least one semiconductor device is disposed in each of the at least three device layers and in the at least one device column. The at least one power signal line column extends along the vertical axis and is disposed on a first end of the IC. The at least one data signal line column extends along the vertical axis and is disposed on a second end of the IC. Accordingly, an electrical circuit can be provided, which implements a plurality of integrated circuits, where each integrated circuit has a reduced scaling on the integrated circuit along the vertical axis (e.g., the Z-axis).

In some embodiments, the first integrated circuit and the second integrated circuit are aligned with one another along the first horizontal axis. Accordingly, the electrical circuit provides flexibility on the arrangement of one or more integrated circuits connected to one another, where each integrated circuit has a reduced scaling on the integrated circuit along the vertical axis (e.g., the Z-axis).

In some embodiments, the first integrated circuit and the second integrated circuit are offset with respect to one another along a first horizontal axis (e.g., X-axis). Accordingly, the electrical circuit provides flexibility on the arrangement of one or more integrated circuits connected to another along a first horizontal axis (e.g., X-axis), where each integrated circuit has a reduced scaling on the integrated circuit along the vertical axis (e.g., the Z-axis).

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Various non-limiting embodiments described herein provide an integrated circuit that implements an interconnect device including at least three vertically arranged device levels that contain one or more semiconductor devices. A vertical power signal column extends transversal to the stacked device layers, and a vertical data signal column extends transversal to the stacked device layers. Each device level contains one or more semiconductor devices. A pair of vertically aligned semiconductor devices establishes a stacked semiconductor device. In at least one embodiment, the stacked semiconductor device is a stacked CMOS device, also referred to herein as a “stacked FET” or “SFET”.

The power signal column contains vertically extending electrically conductive power vias that are electrically connected to horizontally extending metal lines that are electrically connected to the stacked CMOS devices. The data signal column contains vertically extending electrically conductive data vias that are electrically connected to the stacked CMOS devices. According to a non-limiting embodiment, the power vias connect the stacked CMOS devices to a backside of the integrated circuit, while the data signal lines connect the stacked CMOS devices to the frontside of the integrated circuit. As described herein, the interconnect structure can be viewed as the power and data signal columns, and the electrical connections they establish between the first and second CMOS devices. The unique connection facilitated by the interconnect structure allows for reducing the total area of an integrated circuit by scaling the integrated circuit along the Z-axis. In one or more non-limiting embodiments, data signal lines can be routed on the front or backside of the integrated circuit and the power vias may be routed on the front or backside of the integrated circuit. In at least one embodiment, the unique connection allows for further area scaling on the integrated circuit in the Z-axis whereas previously scaling achieved by conventional integrated circuits was limited to the X/Y axis only.

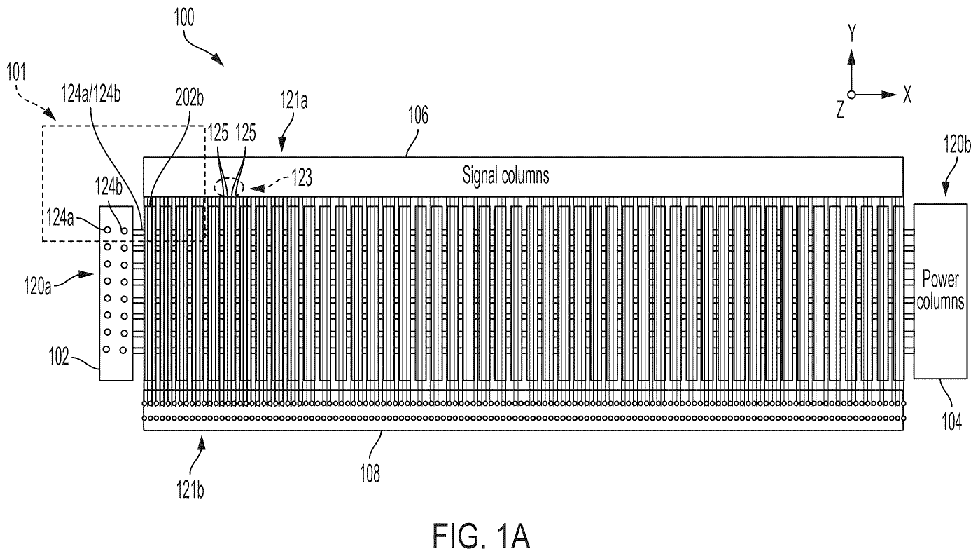

With reference now to FIGS. 1A and 1B, an integrated circuit 100 including an interconnect structure having multiple device layers is illustrated according to a non-limiting embodiment of the present disclosure. The integrated circuit 100 extends along a first axis (X-axis) between a first end 102 and a second end 104 located opposite the first end to define a length, along a second axis (Y-axis) orthogonal to the first axis between a third end 106 and a fourth end 108 located opposite the third end to define a width, and along a third axis (Z-axis) orthogonal to the first and second axes between a frontside 110 of the integrated circuit and a backside 112 of the integrated circuit (see FIG. 1B) to define a vertical height.

FIG. 1B is a logic slice 101 of the integrated circuit 100 shown in FIG. 1A. The logic slice 101 depicts the integrated circuit 100 as having four device layers 114a, 114b, 114c, and 114d (collectively referred to as device layers 114a-114d) and four device columns 116a, 116b, 116c, and 116d (collectively referred to as device columns 116a-116d). Although four device layers 114a-114b and four device columns 116a-116d are shown, it should be appreciated that the integrated circuit 100 can be implemented with three or more device layers and at least one device column without departing from the scope of the invention.

Each of the device layers 114a-114d are vertically arranged along the third axis (Z-axis), e.g., are stacked, and are separated from one another by a horizontal space 115 extending along the second axis (Y-axis). Accordingly, each device layer 114a-114d extends along the first axis (X-axis) to define a layer length and the second axis (Y-axis) to define a layer width. The device columns 116a-116d extend vertically along the third axis (Z-axis) to define a column height. Each device column 116a-116d is separated from one another by a column space 117, which extends vertically along the third axis (Z-axis).

Each device layer 114a-114d contains at least one semiconductor device 200a, 200b, 200c and 200d (collectively referred to as 200a-200d); however, the device layers typically include a plurality of semiconductor devices. Each semiconductor device 200a-200d can be implemented as one of a p-type field effect transistor (referred to herein as a PFET) or an n-type field effect transistor (referred to herein as an NFET). The PFET or NFET are constructed as nanosheet FETs in one or more embodiments. It should be appreciated, however, that the PFET or NFET can be constructed in line with other FET architectures including, but not limited to, finFETs, nanowire FETS, and gate-all-around FETs.

With continued reference to FIG. 1B, the combination of a first semiconductor device (e.g., semiconductor device 200a) located in a first device layer (e.g., device layer 114a) and a first device column (e.g., device column 116a), and a second semiconductor device (e.g., semiconductor device 200b) located in a second device layer (e.g., device layer 114b) and the first device column (e.g., device column 116a) establishes a first stacked complimentary metal-oxide semiconductor (CMOS) device 202a residing in a corresponding device column (e.g., device column 116a). Likewise, the combination of a third semiconductor device (e.g., semiconductor device 200c) located in a third device layer (e.g., device layer 114c) and the first device column (e.g., device column 116a), and a fourth semiconductor device (e.g., semiconductor device 200d) located in a fourth device layer (e.g., device layer 114d) and the first device column (e.g., device column 116a) establishes a second stacked complimentary metal-oxide semiconductor (CMOS) device 202b residing in the first device column (e.g., device column 116a). Unlike conventional integrated circuits, the integrated circuit 100 described according to various non-limiting embodiments of the present disclosure implements a unique interconnect structure that allows for stacking two or more CMOS devices in the same device column. In this manner, a reduced vertically scaling of the integrated circuit 100 in the z-axis direction can be achieved.

Continuing reference to FIGS. 1A and 1B, the integrated circuit 100 includes a pair of power signal columns 120a and 120b (e.g., first-type signal columns), and a pair of data signal columns 121a and 121b (e.g., second-type signal columns). The power signal columns 120a and 120b are disposed adjacent to the first end 102 and the second end 104, respectively, and extend along the third axis (Z-axis) orthogonally with respect to the horizontal device layers 114a-114d. Each power signal column 120a and 120b contains a pair of power signal lines 124a and 124b (e.g., first-type signal lines) comprising an electrically conductive material such as, for example, metal, which establishes a first electrical connection with each of the semiconductor devices 200a-200d disposed in the device layers 114a-114d. According to a non-limiting embodiment, a first power signal line 124a is utilized as a voltage source (VSS) power line and a second power signal line 124b is utilized as a voltage drain (VDD) power line. It should be appreciated, however, that the first and second power signal lines 124a and 124b can both be implemented as VSS power lines or can both be implemented as VDD power lines.

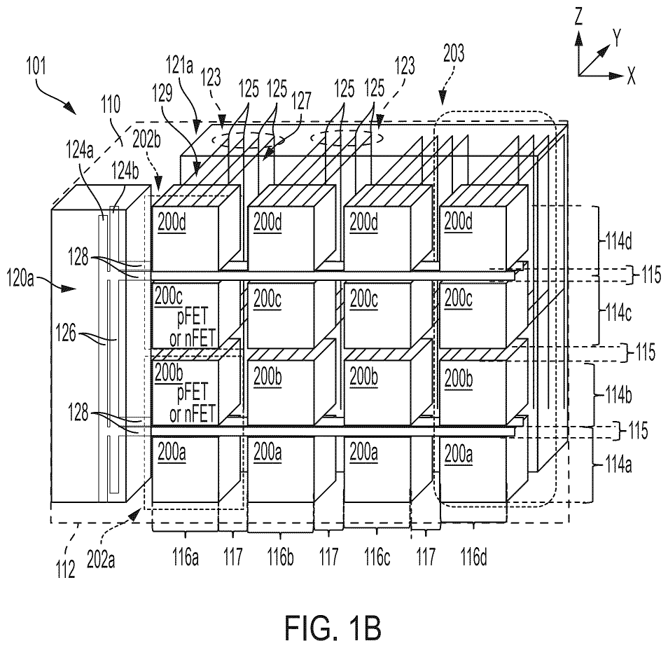

The first and second power signal lines 124a and 124b each include a vertical power line portion 126 and one or more horizontal power line portions 128. The vertical power line portion 126 extends vertically along the third axis (Z-axis). According to a non-limiting embodiment, the vertical power line portion 126 can be implemented using a plurality of vertically stacked power vias formed of an electrically conductive material. Each horizontal power line portion 128 extends along the first axis (X-axis) and through the horizontal space 115 separating an NFET and a PFET of a given stacked CMOS device 202a and 202b. According to a non-limiting embodiment, the vertical power line portion 126 can be implemented using a plurality of signal vias 130 comprising an electrically conductive material (e.g., metal) as depicted in FIGS. 2B and 2C. Accordingly, the conductive signal vias 130 are connected to the horizontal power line portions 128 to establish electrical conductivity with each of the horizontal power line portions 128.

The data signal columns 121a and 121b are disposed adjacent the third end 106 and the fourth end 108, respectively. Each of the data signal columns 121a and 121b contain a plurality of data signal lines 125 (e.g., second-type signal lines), which establishes a second electrical connection with one or more of the semiconductor devices 200a-200d disposed in the device layers 114a-114d . . . . The data signal lines 125 are configured to deliver various data and information to and from a corresponding stacked CMOS device 202a and 202b. The data and information includes, but is not limited to, intra-cell routing, global signal routing, and clock signals.

As shown in FIG. 1B, each stacked CMOS device 202a and 202b is electrically connected to a subset of the data signal lines 125, and each data signal line 125 within the subset is exclusively connected to one of the stacked CMOS devices 202a and 202b. Although the subset of data signal lines 125 is shown as having four data signal lines connected to a given stacked CMOS device 202a, 202b, it should be appreciated that the subset can include more or less data signal lines 125 without departing from the scope of the invention.

According to a non-limiting embodiment, each of the data signal lines 125 includes a vertical data line portion 127 and a horizontal data line portion 129. The vertical data line portion 127 extends vertically along the third axis (Z-axis). The horizontal data line portion 129 extends along the second axis (Y-axis) from a first horizontal end connected to a given stacked CMOS device 202a, 202b to a second horizontal end connected to the vertical data line portion 127.

As described herein, the power signal columns 120a and/or 120b, the data signal columns 121a and/or 121b, and the unique electrical connections achieved using the power signal lines 124a, 124b and the data signal lines 125 (e.g., with one or more columns of stacked CMOS devices 200a, 200b) effectively establishes an interconnect structure that allows for reducing the total area of an integrated circuit 100 by scaling along the Z-axis.

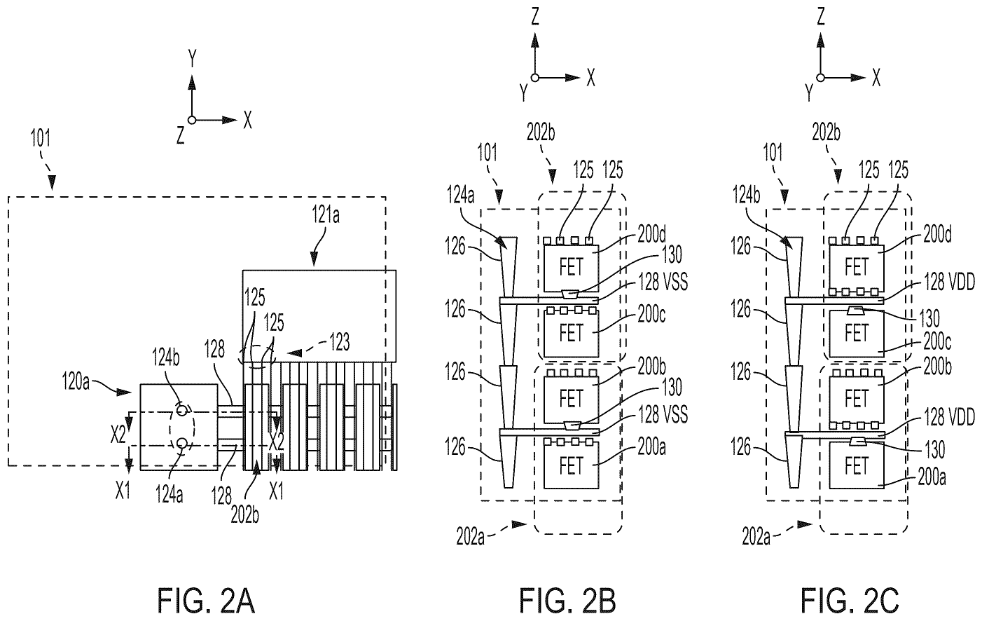

The first and second power signal lines 124a, 124b, and the data signal lines 125 can be formed to provide various signal routing arrangements. Turning to FIGS. 2A, 2B and 2C, for example, the power signal lines 124a, 124b are shown having a side-by-side routing arrangement. In the side-by-side routing arrangement the first power signal line 124a can be connected to the one of the semiconductor devices, e.g., semiconductor devices 200b, 200d of the stacked CMOS device 202a, 202b using conductive signal vias 130 formed of an electrically conductive material (see FIG. 2B), while the second power signal line 124b can be connected to the other semiconductor devices, e.g., semiconductor devices 200a, 200c of the stacked CMOS device 202a,202b using conductive signal vias 130 (see FIG. 2C). As shown in FIG. 3, for example, the conductive signal vias 130 can be used to connect the horizontal power line portion 128 of the first power signal line 124a to a source 302 of the one of the semiconductor devices, e.g., semiconductor device 200d of a stacked CMOS device, e.g., semiconductor device 202b, and the horizontal power line portion 128 of the second power signal line 124b to a drain 304 of the semiconductor device, e.g., semiconductor device 200d of the stacked the semiconductor devices, e.g., semiconductor device 200d. Accordingly, the gate region 306 for the semiconductor devices, e.g., semiconductor device 200d, can be formed to establish a stacked CMOS device (e.g., stacked CMOS device 202b).

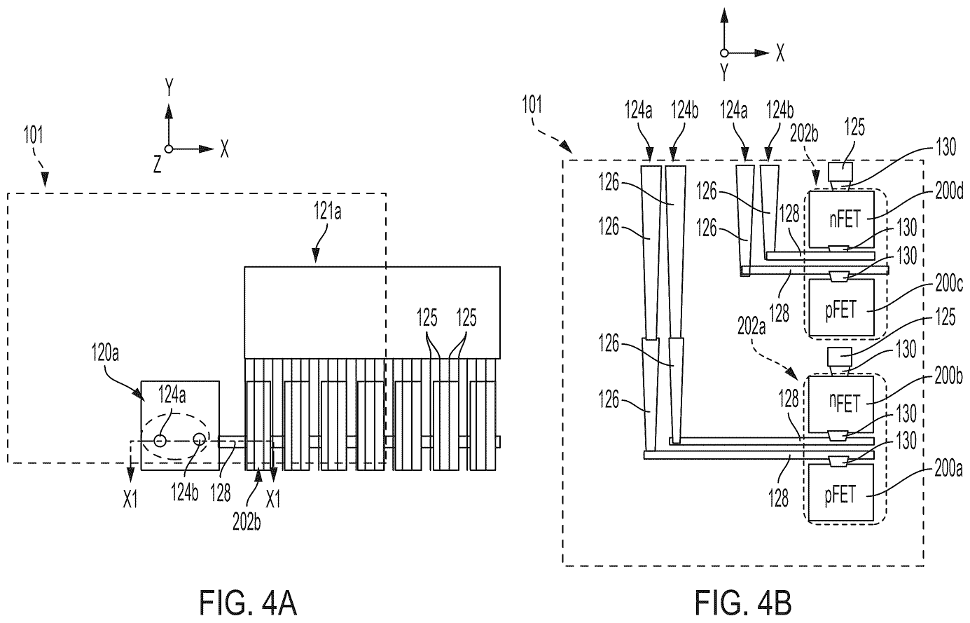

The data signal lines 125 can also be formed according to a side-by-side routing arrangement (see FIG. 5). Accordingly, the horizontal power line portions 128 of the first and second power signal lines 124a, 124b and the horizontal data line portions 129 of the data signal lines 125 can be routed side-by-side, which allows for reducing the vertical footprint of the integrated circuit 100.

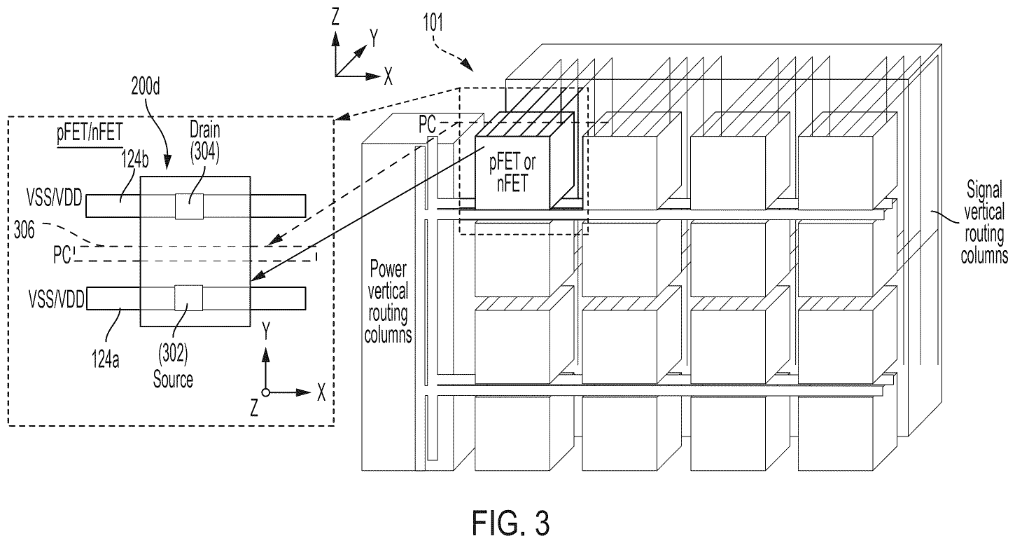

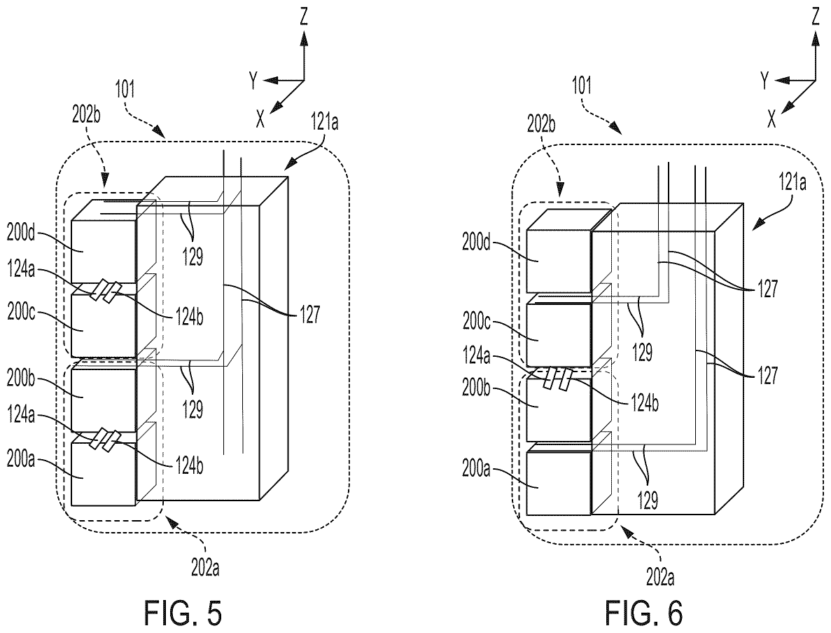

FIGS. 4A and 4B show the first and second power signal lines 124a, 124b in a stepped routing arrangement. In the stepped routing arrangement the horizontal power line portions 128 of the power signal lines 124a, 124b can be vertically aligned (e.g., along the Z-axis) with respect to one another, while the vertical power line portions 126 are stepped along the horizontal axis (e.g., X-axis). Likewise, the data signal lines 125 can be formed according to a stepped routing arrangement (see FIG. 6). Accordingly, the horizontal footprint of the integrated circuit 100 can be reduced. The stepped arrangement shown in FIGS. 4A and 4B may also be applied to the example embodiment shown in FIG. 3.

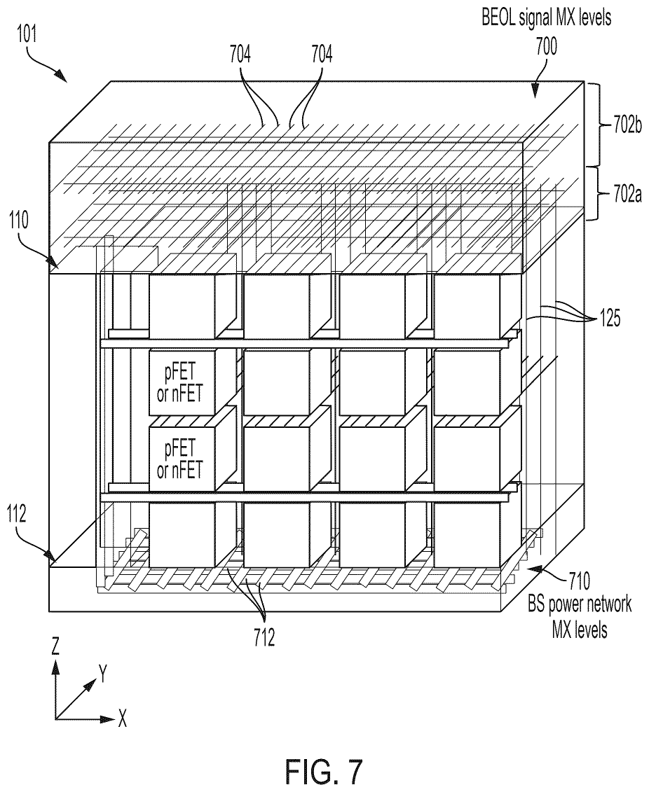

Turning now to FIG. 7, the logic slice 101 of the integrated circuit 100 is illustrated following the formation of a backend-of-line (BEOL) metal level 700 and a power distribution network 710 according to a non-limiting embodiment of the present disclosure. The BEOL metal level 700 (e.g., a frontside BEOL metal level 700) is formed on the frontside 110 of the integrated circuit 100 and includes one or more metal layers 702a, 702b. Each metal layer 702a, 702b includes a plurality of metal interconnect lines 704 that are electrically connected to the plurality of data signal lines 125.

The power distribution network 710 (e.g., a backside power distribution network or “BS-PDN”) is formed on the backside 112 of the integrated circuit 100 and includes a plurality of metal power lines 712 that are electrically connected to the first and second power signal lines 124a and 124b. Although the power distribution network 710 is described as being formed on the backside 112, it should appreciated that the power distribution network 710 can be formed on the frontside 110, or on both the backside 112 and the frontside 110).

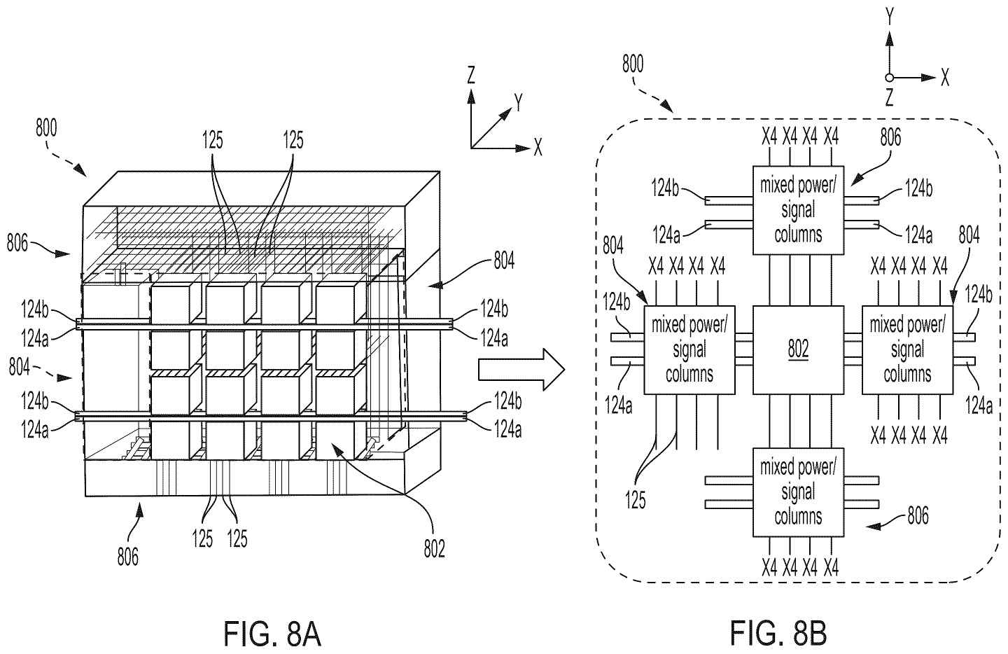

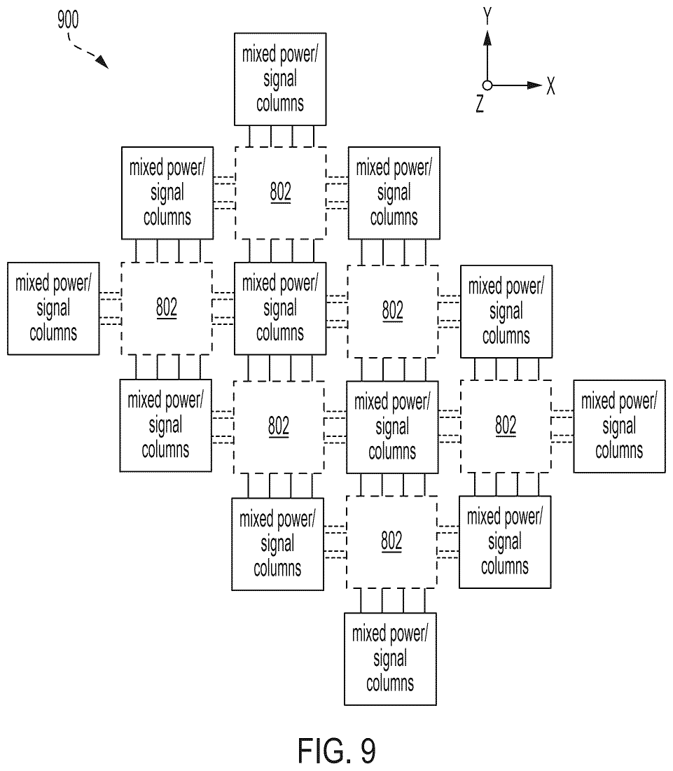

Referring now to FIGS. 8A and 8B, an integrated circuit chip (IC chip) 800 arranged using the interconnect structure described herein is illustrated according to a non-limiting embodiment of the present disclosure. FIG. 8A is a perspective view of the IC chip 800, while FIG. 8B is a block diagram of the IC chip 800. The IC chip 800 includes an integrated circuit 802, an opposing pair of power signal columns 120a, 120b, and an opposing pair of data signal columns 121a, 121b. The opposing pair of power signal columns 120a and 120b allows for connecting one or more additional IC chips 800 to share a power source using power signal lines 124a and 124b, while the opposing pair of data signal columns 121a and 121b allows for connecting one or more additional IC chips 800 to share data using data signal lines 125. As shown in FIG. 9, multiple IC chips 800 can be connected together to form an electrical circuit 900. The number of power signal columns 120a, 120b and the number of data signal columns 121a, 121b can vary by design, as well as the distance between the power signal columns 120a, 120b and the data signal columns 121a, 121b.

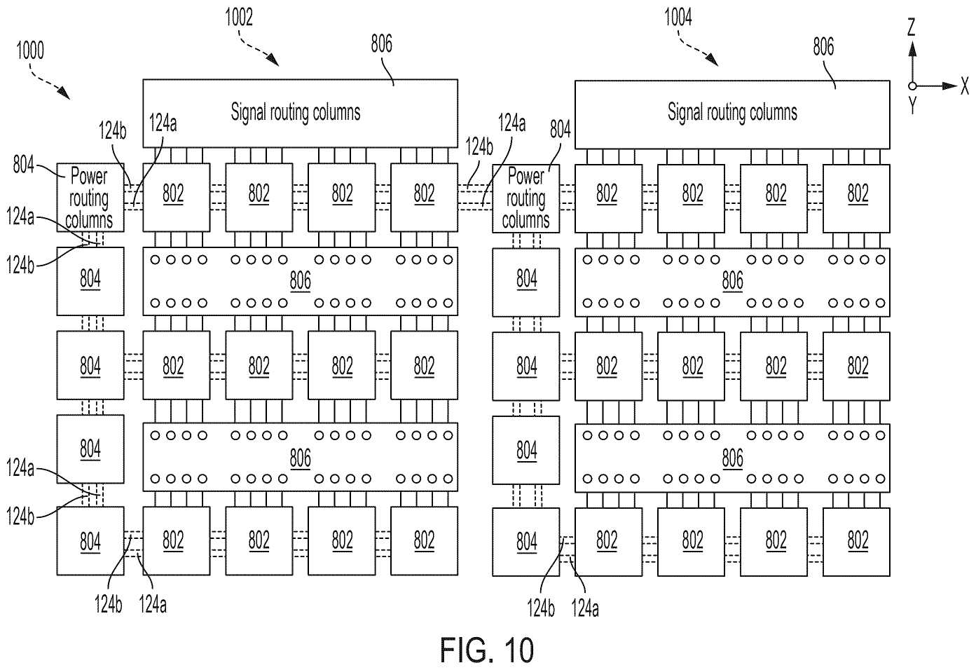

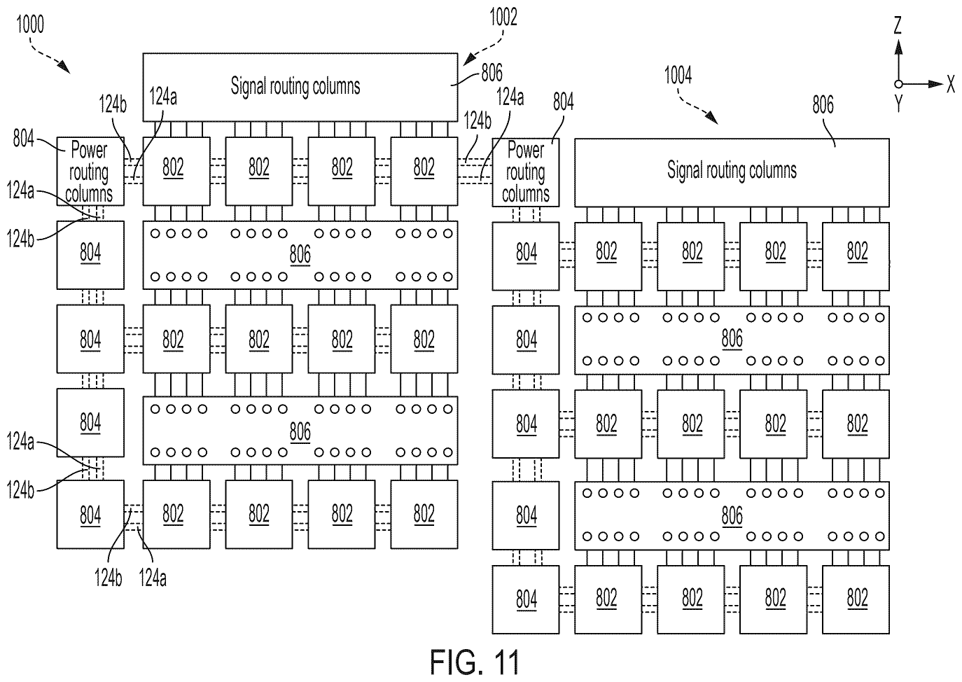

The power signal columns 120a, 120b also allow for establishing an electrical circuit that connects two or more integrated circuits in various different arrangements. As shown in FIG. 10, for example, an electrical circuit 1000 is shown including a first integrated circuit 1002 electrically connected to a second integrated circuit 1004 using the interconnect structure described herein. According to a non-limiting embodiment, the first integrated circuit 1002 and the second integrated circuit 1004 each include at least three device layers arranged along a vertical axis, at least one semiconductor device, at least one semiconductor device, at least one first power signal line column, and at least one second power signal line column (see e.g., FIGS. 1A and 1B). In a first example shown in FIG. 10, the first integrated circuit 1002 and the second integrated circuit 1004 are aligned with one another, e.g., along the X-axis. FIG. 11 shows the electrical circuit 1000 in a different connection arrangement. In this example, the first integrated circuit 1002 and the second integrated circuit 1004 are offset with respect to one another, e.g., along the X-axis.

As described herein, various non-limiting embodiment of the present disclosure provide an integrated circuit that implements an interconnect device including at least three vertically arranged device levels that contain semiconductor devices that can establish a stacked CMOS device. A vertical power signal column extends transversal to the stacked device layers, and a vertical data signal column extends transversal to the stacked device layers. Each device level contains one or more semiconductor devices. A pair of vertically aligned semiconductor devices establishes a stacked CMOS device. The power signal column contains vertically extending electrically conductive power vias that are electrically connected to horizontally extending metal lines that are electrically connected to the stacked CMOS devices. The data signal column contains vertically extending electrically conductive data vias that are electrically connected to the stacked CMOS devices. The power vias connect the stacked CMOS devices to a frontside backside of the integrated circuit, while the data signal lines connected the stacked CMOS devices to the frontside of the integrated circuit. As described herein, the interconnect structure can be viewed as the power and data signal columns, and the electrical connections they establish between the first and second CMOS devices. The unique connection facilitated by the interconnect structure allows for reducing the total area of an integrated circuit 100 by scaling the integrated circuit along the Z-axis.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

For the sake of brevity, conventional techniques related to making and using aspects of the invention may or may not be described in detail herein. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description, but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. An integrated circuit extending along a first axis between a first end and a second end located opposite the first end to define a length, extending along a second axis orthogonal to the first axis between a third end and a fourth end located opposite the third end to define a width, and extending along a third axis orthogonal to the first and second axes between a frontside of the integrated circuit and a backside of the integrated circuit to define a vertical height, the integrated circuit comprising:
at least three device layers arranged along the third axis and separated from one another by a horizontal space extending along the second axis, and at least one at least one device column extending along the third axis;
at least one semiconductor device disposed in each of the at least three device layers and aligned vertically in the at least one device column;
at least one first-type signal line column extending along the third axis, the at least one first-type signal line column including a plurality of first-type signal line pairs that extend along the first axis to establish a first electrical connection with the at least one semiconductor device disposed in the at least three device layers; and
at least one second-type signal line column that extends along the third axis, the at least one second-type signal line column including at least one second-type signal line that extends along the second axis to establish a second electrical connection with the at least one semiconductor device disposed in the at least three device layers.

2. The integrated circuit of claim 1, wherein a pair of vertically aligned semiconductor devices among the at least three device layers form a stacked complimentary metal-oxide semiconductor (CMOS) device.

3. The integrated circuit of claim 2, wherein the plurality of first-type signal line pairs are established as first and second power signal lines, and the at least one second-type signal line is established as a data signal line.

4. The integrated circuit of claim 3, wherein each of the first and second power signal lines include a vertical power line portion extending vertically along the third axis and a plurality of horizontal power line portions.

5. The integrated circuit of claim 4, wherein each of the plurality of horizontal power line portions extend along the first axis to provide power to the at least one semiconductor device.

6. The integrated circuit of claim 5, wherein each of the plurality of horizontal power line portions are arranged side-by-side with respect to one another.

7. The integrated circuit of claim 5, wherein each of the plurality of horizontal power line portions are vertically aligned along the third axis with respect to one another.

8. The integrated circuit of claim 5, wherein the vertical power line portion includes a plurality of vertically stacked signal vias formed from an electrically conductive material.

9. The integrated circuit of claim 2, wherein the at least one semiconductor device included in a first device layer among the at least three device layers is an n-type field effect transistor (NFET) and the at least one semiconductor device included in a second device layer among the at least three device layers is a p-type field effect transistor (PFET).

10. The integrated circuit of claim 2, wherein the at least one semiconductor device included in a first device layer among the at least three device layers is an p-type field effect transistor (PFET) and the at least one semiconductor device included in a second device layer among the at least three device layers is an n-type field effect transistor (NFET).

11. The integrated circuit of claim 1, wherein the at least one first-type signal line column includes a pair of first-type signal line columns disposed adjacent to the first end and the second end of the integrated circuit, respectively.

12. The integrated circuit of claim 1, wherein the at least one second-type signal line column includes a pair of second-type signal line columns disposed adjacent to the third end and the fourth end of the integrated circuit, respectively.

13. The integrated circuit of claim 1, further comprising:
a backend-of-line (BEOL) metal level on the frontside of the integrated circuit; and
a power distribution network on the backside of the of the integrated circuit.

14. The integrated circuit of claim 3, wherein:
the first power signal line is a voltage source (VSS) power line and the second power signal line is a voltage drain (VDD) power line; and
the at least one second-type signal line includes a plurality of data signal lines.

15. An integrated circuit (IC) chip comprising:
an IC comprising:
at least three device layers arranged along a vertical axis, the at least three device layers separated from one another by a horizontal space extending along a first horizontal axis and by at least one device column extending along the vertical axis;
at least one semiconductor device disposed in each of the at least three device layers and in the at least one device column;
a first power signal line column extending along the vertical axis and disposed on a first end of the IC;
a second power signal line column extending along the vertical axis and disposed on a second end of the IC opposite the first end;
a first data signal line column extending along the vertical axis and disposed on a third end of the IC; and
a second data signal line column extending along the vertical axis and disposed on a fourth end of the IC opposite the third end.

16. The IC chip of claim 15, wherein each of the first power signal line column and the second power signal line column includes a first power signal line and a second power signal line, and wherein each of the first data signal line column and the second data signal line column includes at least one data signal line.

17. The IC chip of claim 16, wherein each of the first power signal line and a second power signal line includes a vertical power line portion extending along the vertical axis and at least one horizontal power line portion extending along the first horizontal axis.

18. The IC chip of claim 17, wherein the vertical power line portion includes at least one signal via connected to that at least one horizontal power line portion.

19. The IC chip of claim 16, wherein the at least one data signal line includes a vertical data line portion extending along the vertical axis and a horizontal data line portion extending along a second horizontal axis orthogonal to the first horizontal axis.

20. An electrical circuit comprising:
a first integrated circuit and a second integrated circuit electrically connected to the first integrated circuit, each of the first integrated circuit and the second integrated circuit comprising:
at least three device layers arranged along a vertical axis, the at least three device layers separated from one another by a horizontal space extending along a first horizontal axis and by at least one device column extending along the vertical axis;
at least one semiconductor device disposed in each of the at least three device layers and in the at least one device column;
at least one first power signal line column extending along the vertical axis and disposed on a first end of the IC; and
at least one data signal line column extending along the vertical axis and disposed on a second end of the IC.

21. The electrical circuit of claim 20, wherein the at least one power signal line column includes a first power signal line and a second power signal line, and wherein the at least one data signal line column includes at least one data signal line.

22. The electrical circuit of claim 21, wherein the first power signal line and the second power signal line each includes a vertical power line portion extending along the vertical axis and at least one horizontal power line portion extending along the first horizontal axis.

23. The electrical circuit of claim 21, wherein the at least one data signal line includes a vertical data line portion extending along the vertical axis and a horizontal data line portion extending along a second horizontal axis orthogonal to the first horizontal axis.

24. The electrical circuit of claim 21, wherein the first integrated circuit and the second integrated circuit are aligned with one another along the first horizontal axis.

25. The electrical circuit of claim 21, wherein the first integrated circuit and the second integrated circuit are offset with respect to one another along the first horizontal axis.
